(19) United States
(12) Patent Application Publication
(10) Pub. No.: US 2015/0155162 A1
(43) Pub. Date: Jun. 4, 2015

(54) Reduction of Charging Induced Damage in Photolithography Wet Process

(71) Applicant: Spansion LLC, Sunnyvale, CA (US)

(72) Inventors: Daniel E. SUTTON, Austin, TX (US); Christopher M. FOSTER, Austin, TX (US); Kelley Kyle HIGGINS, SR., Austin, TX (US); Moutasim KHOGLY, Austin, TX (US); Alexander J. BIERWAG, Austin, TX (US); Daniel H. WILCOX, Round Rock, TX (US)

(73) Assignee: Spansion LLC, Sunnyvale, CA (US)

(21) Appl. No.: 14/095,150

(22) Filed: Dec. 3, 2013

(51) Int. Cl. H01L 21/02; H01L 49/02

(52) U.S. Cl. CPC H01L 21/02164; H01L 28/40; H01L 21/02334; H01L 21/02343

(57) ABSTRACT

An approach is developed to use an acidic rinse to reduce charge during the lithographic process, and thereby eliminate the crystalline damage and associated yield loss associated with the accumulated charge. The crystalline damage has been found to occur for certain thicknesses of dielectric layers, and such damage is irreparable. A sparge can be used to dissolve carbon dioxide in water to provide a weak acidic rinse.

### BACKGROUND

1. Field

This invention relates generally to semiconductor lithography, and more particularly to a semiconductor processing method that avoids substrate charging that can both induce damage and attract particles.

2. Background Art

The semiconductor market has been undergoing extensive growth over the past few decades. This trend is expected to continue for the foreseeable future since consumer products demand more and more electronic-based features. Most electronic features rely on semiconductors, with the complexity and/or density of such semiconductors continuing to increase over time. Although complexity and/or density continue to increase over time, market forces demand that the costs decrease at the same time.

Crucial to the market demand of ever decreasing cost is the ability of semiconductor manufacturers to maintain high wafer yields. Maintenance of high wafer yields requires careful attention to semiconductor processes, and a thorough understanding of the possible failure modes relevant to that particular process. Improved uniformity of materials, process steps and elimination of failure modes all contribute to the high wafer yields so necessary to meet the ever decreasing cost targets.

Flash memory fabrication is no different to those requirements that apply to semiconductor processing in general. In particular, the market demands that flash memory be provided with ever increasing densities, and ever decreasing costs points. Every increasing densities of memory together the need to accomplish such densities at lower and lower costs demands the improved material uniformity, precision of process steps and failure mode elimination noted above. In particular, the semiconductor geometries are becoming smaller, while the need to maximize the wafer real estate is becoming more pronounced.

### BRIEF SUMMARY

In response to the above demands, there is a need to determine the problem and solutions to significant yield problems associated with the formation of memory devices. In particular, there is a need to determine the underlying cause of and provide a satisfactory solution to a substantial yield problem associated with the formation of dielectric layers (e.g., gate oxide, inter-layer dielectric) during patterning of silicon wafers.

In an embodiment of the present invention, the underlying cause was determined to be a substantial but undetected discharge that occurs in dielectric films in a certain thickness range while being patterned by lithography. The damage resulting from the undetected discharge is irreparable damage of the underlying substrate. Thus, even if the dielectric film is subsequently removed (e.g., a sacrificial oxide layer) and other layers take its place, the damage has already occurred in the underlying material (e.g., substrate) and cannot be repaired. In addition, the charge on the wafer surface also increases the sticking of surface particles due to electrostatic attraction.

In place of a deionized (DI) water rinse during the lithography or patterning), embodiments of the present invention use a weak acidic rinse following the patterning of the dielectric films.

In one embodiment, a method is described that forms a dielectric layer over a substrate. The dielectric layer is patterned using a developer having a pH greater than 7. A weak acidic rinse is then applied to the patterned dielectric layer.

The features and advantages of the current invention will become more apparent from the detailed description set forth below when taken in conjunction with the drawings, in which like reference characters identify corresponding elements throughout. In the drawings, like reference numbers generally indicate identical, functionally similar, and/or structurally similar elements. The drawing in which an element first appears is indicated by the leftmost digit(s) in the corresponding reference number.

### BRIEF DESCRIPTION OF THE DRAWINGS/FIGURES

The accompanying drawings, which are incorporated herein and form part of the specification, illustrate the present invention and, together with the description, further serve to explain the principles of the invention and to enable a person skilled in the relevant art(s) to make and use the invention.

FIG. 1 illustrates a Pourbaix diagram for the surface interface of water and a silicon wafer.

FIG. 2 illustrates a hydrogen terminated silicon oxide surface.

FIG. 3 illustrates a deionized (DI) water rinse of hydrogen terminated silicon oxide surface showing the free hydroxyl ion deprotanation.

FIG. 4 illustrates the result of a carbonic acid rinse of hydrogen terminated silicon oxide surface, in accordance with an embodiment of the current invention.

FIG. 5 illustrates an intermediate dielectric layer structure on a semiconductor substrate, with possible charge induced damage underlying the intermediate dielectric layer structure.

FIG. 6 illustrates a carbon dioxide deionized (DI) water sparge for introduction of a weak acidic rinse in a lithographic process, in accordance with an embodiment of the current invention.

FIG. 7 provides a flowchart of a method that introduces an acidic rinse in a lithographic process, according to an embodiment of the current invention.

The features and advantages of the present invention will become more apparent from the detailed description set forth below when taken in conjunction with the drawings, in which like reference characters identify corresponding elements throughout. In the drawings, like reference numbers generally indicate identical, functionally similar, and/or structurally similar elements. The drawing in which an element first appears is indicated by the leftmost digit(s) in the corresponding reference number.

### DETAILED DESCRIPTION OF THE INVENTION

This specification discloses one or more embodiments that incorporate the features of this invention. The disclosed embodiment(s) merely exemplify the invention. The scope of the invention is not limited to the disclosed embodiment(s). The invention is defined by the claims appended hereto.

The embodiment(s) described, and references in the specification to “one embodiment,” “an embodiment,” “an example embodiment,” etc., indicate that the embodiment(s) described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is understood that it is within the knowledge of one skilled in the art to effect such feature, structure, or characteristic in connection with other embodiments whether or not explicitly described.

### Ultrapure Water Chemistry

Ultrapure water (UPW) is used for one main purpose in semiconductor manufacturing, namely to remove particles and chemical residues from the wafer surface. The goals for ultrapure water are to not only remove these particles and chemical residues, but to also be very clean so that it also does not introduce any particles or residues. In other words, ultrapure water must remove particles and residues from the wafer surface, while being completely benign to the process.

An examination of the surface of a semiconductor wafer where ultrapure water has been introduced provides an explanation of the phenomenon involved. In any rinse process (e.g., photolithography, etch, diffusion, thin films and polish), a typical semiconductor wafer surface consists of silicon, silicon dioxide, a metal such as copper or aluminum, and/or a photo resist. In addition, and depending on the preceding process, the semiconductor wafer surface will be hydrophobic or hydrophilic.

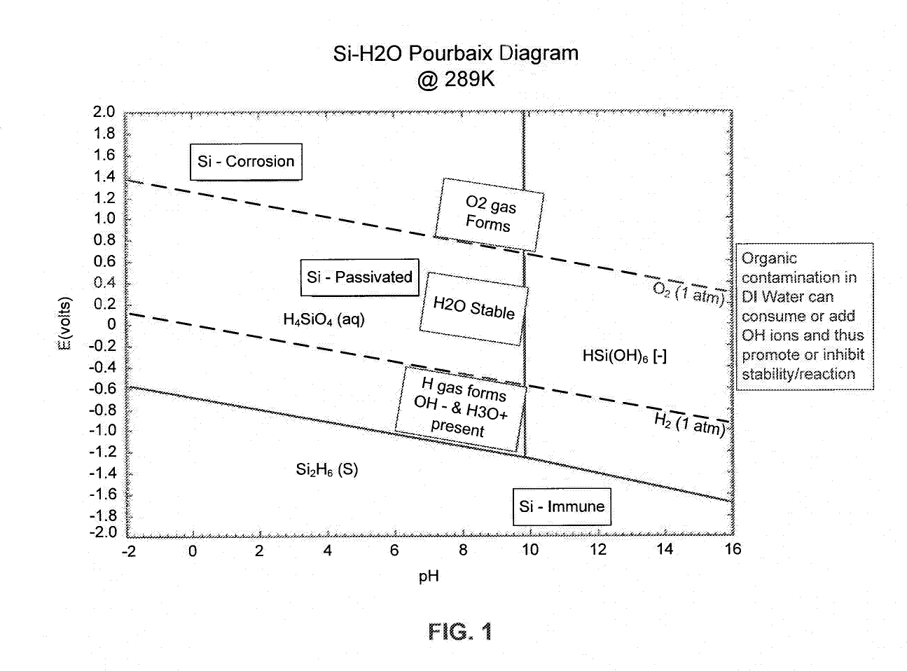

This interaction between ultrapure water and a semiconductor wafer surface can be studied using a Pourbaix analysis. A Pourbaix analysis illustrates how water reacts with the semiconductor wafer surface in terms of phase changes at the surface. An example of a single interaction Pourbaix diagram is illustrated in FIG. 1.

Referring to FIG. 1, this particular Pourbaix diagram represents the surface interface of ultrapure water and a silicon wafer. In particular, the Pourbaix diagram illustrates the relationship between pH (shown on the x-axis) and the electrical potential (Ev) of the solution (shown on the y-axis). Any inorganic or organic impurity in ultrapure water will affect either the pH or the Ev of the interface. Modern ultrapure water systems have been able to achieve extremely low levels of inorganic contamination, for example down to single parts per trillion (PPT) levels. However, organic contamination levels tend to be higher, for example in the 1-2 parts per billion (PPB) range. Referring to FIG. 1, and looking closely at the x-axis, it is known that the pH of ultrapure water can range from 6.8 through 7.2. However, the Ev of the interface can vary significantly with the water still being considered ultrapure water. Theoretically, the Ev value can be monitored with an online instrument that measures Oxidation-Reduction Potential (ORP). However even the most sophisticated ORP instrument available may have precision and accuracy challenges with ultrapure water as the measurement fluid.

Turning now to the molecular chemistry involved, ultrapure water (which is theoretically pure water) exists as continuously transitions of the water, hydronium and the hydroxyl ions, as shown below:

H₃O⁺—H₂O—OH⁻

The presence of inorganic and/or organic compounds in ultrapure water directly affects the kinetics of this transition. Further, the presence of these inorganic and/or organic compounds can theoretically be directly measured by pH and ORP. Referring again to the Pourbaix diagram of FIG. 1, the effect on the silicon by the ultrapure water is represented by the grey squares. For example, in the inner right quadrant where the pH is high and the Ev is low, the silicon is immune to the effects of the ultrapure water. In the middle section of the Pourbaix diagram where the Ev levels are higher and the pH levels are lower, the silicon becomes passivated. Finally, in the upper left of the Pourbaix diagram where the pH levels are low and the Ev levels are high, corrosion of the silicon occurs.

Turning now to the ultrapure water side of the interaction, the lower left of the Pourbaix diagram where the pH levels and the Ev levels are low, hydrogen (H₂) gas will tend to form in the ultrapure water. As the pH and Ev levels are increased, less hydrogen (H₂) gas is formed until the ultrapure water becomes stable as H₂O. Finally, in the upper right region of the Pourbaix diagram, oxygen (O₂) gas will start to form in the ultrapure water. As noted previously, the range of pH values in ultrapure water is very small, but the range of Ev levels can vary significantly. Viewing the Pourbaix diagram where ultrapure water exists in terms of the H₃O⁺—H₂O—OH⁻ transition, ultrapure water will exist more frequently as OH⁻ at the bottom of the diagram when Ev values are low.

### Silicon Oxide Surface Chemistry

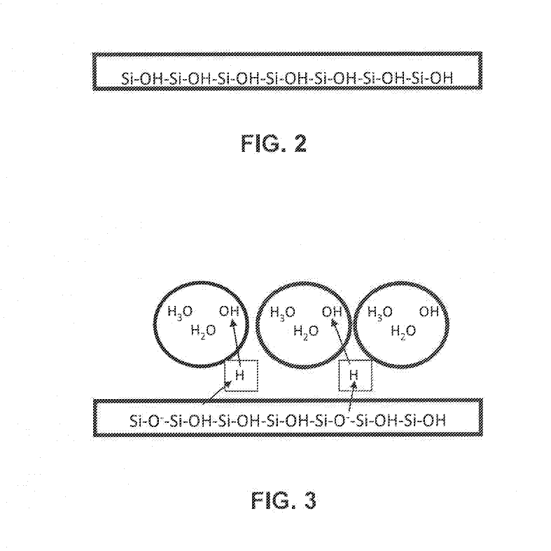

Turning now to the silicon surface in a semiconductor process, the silicon surface may be prepared in many ways depending on the process step. Although there are many ways, a hydrogen terminated silanol surface of SiOH is instructive to analyze, as shown in FIG. 2.

Referring to FIG. 2, if this relatively stable Si—OH surface is rinsed with ultrapure water to remove any particle/chemical residue, and the ultrapure water has a neutral pH and Ev, there should be no reaction between the Si—OH and the ultrapure water. Again by definition, it is known that for ultrapure water its pH is neutral and falls between 6.8 and 7.2. However, if the Ev of the ultrapure water is very high, the ultrapure water will contain O₂ gas which will not have any adverse effects on the surface. However, if the ultrapure water has an Ev that is very low, there will be a high presence of H₂ gas and OH ions in the ultrapure water. These OH ions are highly reactive and try to remove hydrogen from any surface they come into contact with to form H₂O. The OH ions will then remove hydrogen or de-protonate the Si—OH surface leaving regions of Si—O⁻, as shown in FIG. 3.

The most important factor in this interaction is that the surface of the wafer is left with a negative charge. This charged surface can result in many different defects including a region of negative electrical charge that could cause a positively charged particle to deposit on the wafer or if the Si—OH surface is thin enough the charge could dissipate to ground and result in a hole burned in the wafer surface.

The question now comes back to how does all of this relate to total organic carbon (TOC) or organic compounds in ultrapure water?

The discussion now turns to the impact of total organic carbon (TOC) or organic compound content in ultrapure water it is known that modern ultrapure water systems can control inorganic contamination very well to parts per trillion (PPT) levels but organic contamination as TOC is still in the parts per billion (PPB) levels. It is also known that by definition the pH of ultrapure water is in the range of 6.8 to 7.2, but Ev can sway much more drastically. It is also known that Ev is an indication of the presence of hydroxyl ions (OH). The last piece of the puzzle is that it is known that organic compounds react with hydroxyls to form CO₂—H₂O plus other reaction residuals such as Cl, Br, N and P that may be present in the organic compound. Ultrapure water with a TOC of 0 parts per billion (PPB) can be modeled in the lower middle portion of the Pourbaix diagram in FIG. 1. Here, the ultrapure water will have an abundance of OH ions to react with the wafer surface which could result in the defects as described above. As the organic contamination in the ultrapure water increases, the OH ions will be consumed by the oxidation reaction of the organic compound so that the ultrapure water will exist as more H₂O and less OH and H₃O. Furthermore, if those organic compounds are more non-volatile and highly polar, they will consume a higher percentage of OH ions than volatile non polar organics that are easier to oxidize. In addition, the more polar organics will tend to stay dissolved in the ultrapure water and be rinsed away with the ultrapure water. Accordingly, the more polar organics will tend to deposit on the wafer surface. This constitutes another serious defect if the organic stays on the surface during a furnace process and thereby results in the formation of silicon carbide Si—C.

### Proposed Approaches

One of the major problems is that the type of organic in ultrapure water cannot be detected online, only the total content using a TOC monitor. Another problem is that as large variation of the species of organics in the ultrapure water (UPW) is seen depending upon such factors as the seasonal/environmental changes in the source water, the use of reclaimed process rinse water, the breakdown of chemicals/equipment in the UPW water treatment process, the contamination from the distribution piping after treatment, and the contamination from the wafer process tools. All of these are factors in the challenge of measurement and control of “critical” organic compounds in semiconductor ultrapure water (UPW). In addition, it is very expensive to process ultrapure water to achieve TOC levels <1.0 PPB and almost impossible to achieve <0.3 PPB consistently. A further problem is that it also may be detrimental to have a TOC that is “too low” (i.e., UPW “too clean”) where the presence of the OH ions can create defects. An approach to “control” the negative effects of the OH ions is to introduce process robustness in the wafer process so that the wafer is never exposed to the OH ions.

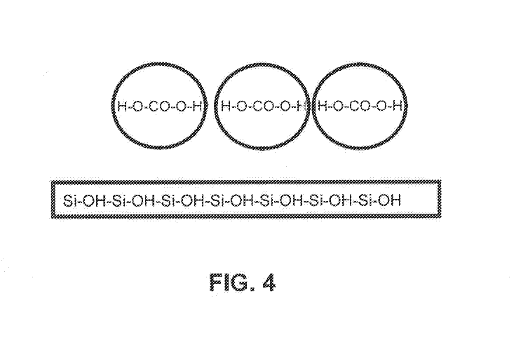

One method is to inject CO₂ into the ultrapure water stream before it contacts the wafer and to control the amount of hydroxyl ions (see FIG. 4) by controlling the resistivity of the ultrapure, water to a value of less than 18 M-Ohms. Another method could be to introduce a controlled amount of a known non-volatile, polar organic chemistry that would perform the same function as the CO₂. An example would be an amide such as urea or caprolactum. This will have the same effect as the organic contamination that consumes the OH ions, but unfortunately the level of organic contamination cannot be controlled, nor can the organic species be controlled to the level that would be required to eliminate how these organic species result in these defects.

The implications of the composition of ultrapure water are substantial. As noted earlier, yield losses in semiconductor processing are significant economic issues since they are direct contributors to the profitability or otherwise of semiconductor manufacturing plants. In particular, flash memory manufacturing involves the fabrication of large numbers of memory cells across a semiconductor wafer. Ideally, there would be minimal yield losses, with virtually all usable real estate of the wafers contributing to the maximization of the efficiency of the fabrication production line.

In addition to the above yield loss pressures, market forces continue to demand that the geometries of individual memory cells decrease in size to thereby result in higher and higher memory cell density on a given wafer. However, it has been noted that yield losses of certain high memory cell density wafers are prone to random yield losses of substantial proportions. Initial indications were that devices such as thin oxide capacitors, for example, were responsible for significant failure rates in these wafers, but the underlying cause was unknown.

Observations regarding these random failures identified a number of trends. In particular, the present inventors have identified the following correlations in their study of the aforementioned failures: (1) there appeared to be a seasonal variation in the observed yield losses over a 12 month period; (2) different input sources of factory water were associated with different yield losses; (3) different developer rinse times in lithographic patterning were associated with different yield losses; (4) the distribution of failures across a number of wafers followed a particular wafer pattern; and (5) yield losses differed depending on the ambient lighting conditions. Further details on each of these observations are provided below.

With respect to seasonal variations, the inventors noticed that yield losses were typically lower in summer, e.g., yield losses in summer were less than five percent. However, in the fall months, yield losses climbed dramatically to reach near fifty percent. Based on the fact that clean room conditions are tightly controlled, the inventors surmised that one variable having potentially seasonal variations would be the incoming water. While incoming water is deionized to remove ions from various sources and many aspect of water quality are tightly controlled (e.g., resistivity, pH), such a process is not perfect. In particular, trace organic impurities may remain in the treated water (also known as deionized water or “DI” water). Further, since organic impurities vary from one season to the next, such organic impurities can result in variation of the free hydroxyl ions present in DI water from one season to the next. The inventors noticed the higher level of defects correlated with seasons of lower organic contamination level.

The current inventors also noted that different sources of water led to dramatically different failure rates. In particular, it was noticed that factory reclaimed DI water and incoming municipal water led to very different failure rates. In semiconductor factories, reclaimed water is effluent DI water that has been treated (e.g., using reverse osmosis) to remove certain impurities from a previous factory processing cycle. Just like the deionization process, the reclamation process is not perfect and therefore some impurities will remain. In the case of reclaimed water, impurities such as simple alcohols (e.g., ethanol, propanal and isopropyl alcohol) and other organic chemicals (e.g., carbamide) can be expected to remain in the water. Thus, given that different impurities are present in reclaimed water versus those in municipal water, one can expect different impacts on the wafer manufacturing process. These impurities can be categorized based on the polarization of the molecules of the impurities leading to higher levels of free hydroxyl ions present in the DI water.

In a further investigation, developer rinse times also appeared to have a substantial impact on the yield losses. For example, a developer rinse time of 21 seconds typically shows significantly reduced yield losses compared to the use of a longer developer rinse time of 80 seconds. For example, in one set of experiments, a developer rinse time of 21 seconds resulted in a wafer defect count of 99. At a developer rinse time of 28 seconds, the defect count climbed to 4732, while at a developer rinse time of 35 seconds, the defect count rose to the maximum count of 24,970 available using the metrology available. Visual indications indicated that developer rinse times of 42 seconds, 60 seconds and 80 seconds resulted in defect count that exponentially increased with increasing rinse time. Other developer rinse process factors that increase defect counts are higher wafer spin speed and higher water flow rates.

While performing the developer rinse time experiments, the pattern of wafer defects was noted. In all cases, the wafer defect pattern constituted a bull's-eye pattern, with the greatest density of defects found close to the center of the wafer. As the number of defects increased, the bull's eye pattern expanded outwards from the center of the wafer. Such an observation suggested that the underlying cause of the defect was always more prominent at the center of the wafer.

Finally, it was observed that wafer processing in a lithography production line using low ambient illumination resulted in lower yield losses than a comparable lithography production line using normal ambient illumination. It is known in the art that the existence of light near a wafer can be associated with increased charging of the wafer. Thus, the interplay between illumination and yield losses suggested wafer charging as a possible cause of the unexpected yield losses.

Previous contributions to the art have recognized the phenomenon of process-induced charge, but such contributions have been limited to process-induced charging in the context of wafer cleaning. For example, Spicer et al., “Controlling Process-induced Charging,” Semiconductor International Magazine, March 2009, pp. 2-6 (hereafter Spicer) reports on process-induced charging that can impact device performance in three ways: physically causing electrostatic discharge events and galvanic metal corrosion, electrically resulting in shifts in critical device performance characteristics, and in-field reliability leading to changes in critical parameters such as time-dependent dielectric breakdown. However, while acknowledging the process-induced charging phenomenon, Spicer and similar papers refer generally of the dangers of excess voltage to gate oxide structures of various thicknesses. Despite the general discussion, Spicer notes that although charging can be reduced, the use of remedial actions (such as the introduction of carbon dioxide) does not come without cost. For example, Spicer notes that it adds further complications to the wafer-clean rinse optimization. Such complications include a resulting increase in the incidence of corrosion in copper lines, as well as an acknowledgement that there may still be sufficient charging so as to induce explosions in films, even when carbon dioxide is introduced. Thus, Spicer does not recommend the use of carbon dioxide, but instead recommends the use of real-time charge measurement.

In addition to industry recommendations against the use of carbon dioxide, the present inventors are unaware of any research that pinpoints the crucial role played by various intermediate structures that are formed during photolithography, and their implication in a failure mechanism a process-induced charging phenomenon. For example, instead of any focus on the intermediate structures, Spicer recommends the use of real-time charge measurement that can be used to explore and image the wafer surface during its processing. Thus, Spicer's approach is that charge can be monitored and real-time control measures implemented to ensure that finished gate oxide structures are not prone to failure.

Contrary to the recommendations from Spicer and others in the field, the inventors have found the yield problem to be far beyond the superficial focus on finished gate oxide structures and real-time monitored charge levels on the wafers. In fact, a focus on only the finished gate oxide thickness, its associated breakdown voltage and the maintenance of the real-time wafer charge level below the breakdown voltage was found by the current inventors to do little to reduce the significant yield losses in high density memory cell fabrication. Ironically, the present inventors have noted that while the charging effects of deionized (DI) water have been known in wet chemistry (i.e., rinsing) for many years, the connection between DI water and process-induced charging effects in a lithography production process were unknown.

For example, the present inventors have found that a focus on the charging effects during intermediate lithography steps are crucial to successful yield management of high density memory cell fabrication. In particular, the present inventors have determined that there is a critical range of gate oxide thicknesses that can result in an irreversible yield loss problem. If the gate oxide thickness is larger than an upper limit of the critical range, then there is no effect on the underlying silicon substrate as the dielectric breakdown voltage is too large to be threatened by wafer charge buildup during an intermediate lithography step. Similarly, if the gate oxide layer is thinner than the lower limit of the critical range, then there is also no effect since quantum mechanical tunneling effects serve to eliminate the prospect of damage resulting from wafer charge buildup. Thus, there is a critical range of gate oxide thickness (defined as that oxide thickness range between the upper and lower limits) where irreversible yield loss poses a substantial threat. More generally, this critical range of dielectric layer thickness can be referred to as the range of vulnerability to charge-induced damage. Since dielectric (e.g., oxide) thicknesses are determined by semiconductor design considerations, it is not feasible for a semiconductor manufacturing facility to exclude certain oxide thicknesses from its standard processes. Instead, a solution must be found that ensures a high yield fabrication of all oxide thicknesses that are required to support current generation high density semiconductor device fabrication.

Further, the present inventors have also determined that the yield management issue goes well beyond considerations of the critical range of finished gate oxide thicknesses. Quite unexpectedly, the present inventors have determined that other dielectric layers, including intermediate dielectric structures, are vulnerable to this yield loss damage mechanism. Importantly, such damage is irreparable. In fact, this type of “intermediate layer” yield loss mechanism can occur in any photolithographic step whereby a thin dielectric layer (typically an oxide layer) is formed and a sufficient charge is discharged through that thin dielectric layer. This unexpected finding is particularly relevant to memory applications due to the prevalence of intermediate oxide layers whose thicknesses fall into the critical range. Thus, due to the large voltages on the wafers resulting from wafer charge buildup, there can be significant yield loss resulting from the localized discharge of the induced voltage. Not only was this finding surprising given the conventional focus on finished gate oxide structures, but other types of semiconductor circuits (i.e., non-memory semiconductor structures) may not encounter this problem due to their particular range of dielectric layer thicknesses. In other words, the incidence of this problem appears to have been raised initially in high density flash memory cell fabrication. For example, non-memory dielectric layer thicknesses (such as those dielectric layers found in logic circuit fabrication) are much thinner than those dielectric layers found in the fabrication of flash memory cells. Thus, the type of yield issue in flash memory cell fabrication does not appear in other high volume semiconductor fabrication processes.

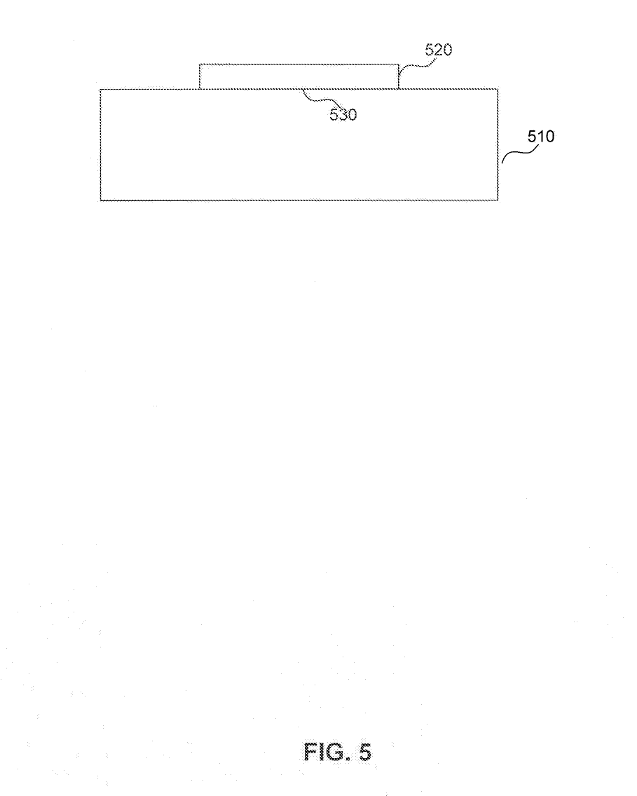

FIG. 5 illustrates an exemplary intermediate dielectric layer structure that may be subject to charge induced damage. A lithographic process results in an intermediate dielectric layer structure 520 on a substrate 510. Substrate 510 can include bulk semiconductor substrates such as silicon, bulk semiconductor substrates together with added layers such epitaxial layers or disposed layers of other materials. If the thickness of dielectric layer structure 520 falls within a critical range, charge buildup can result in damage both to dielectric layer 520 as well as the region 530 immediately adjacent to intermediate dielectric layer structure 520. In an exemplary embodiment, the thickness of the dielectric layer structure lies within the range of about 70 to 120 Angstroms. Importantly, even if intermediate dielectric layer structure 520 is removed, as would be the case if intermediate dielectric layer structure 520 is a sacrificial layer, region 530 remains irreparably damaged. In particular, when subsequent semiconductor features are formed over region 530, the expected performance from the semiconductor features may not be realized due to the semiconductor substrate damage.

As noted above, the inventors have discovered that one of the crucial issues with “intermediate layer” yield loss mechanism is that it cannot be reversed. This problem is applicable to any photolithographic step whereby a thin dielectric layer (typically oxide layer) is laid down and a sufficient charge is discharged through that thin dielectric layer. In particular, what makes this problem particularly relevant to memory applications is the prevalence of intermediate oxide layers whose thicknesses fall into the vulnerable range. The abundance of hydroxyl ions in the DI watery leads to deprotanation of the dielectric film surface resulting in a localized charged region of the wafer surface. Thus, due to the large voltages on the wafers resulting from a DI water rinse, there can be significant yield loss resulting from the localized discharge of the voltage. In contrast, other types of semiconductor circuits may not encounter this problem, if their dielectric layer thicknesses are such that the discharge does not occur, or is precluded from occurring by tunneling. For example, logic circuits typically use much thinner oxide layers than those in flash memory circuits.

Further complicating the identification of the “intermediate layer” yield loss mechanism is the inability to readily locate the damage that results from the localized discharge. Indeed, the damage is not at all obvious to the casual observer. These defects are very hard to locate, and can typically be observed only if one is already alerted to the problem, and therefore specifically searching for the problem. In particular, the location of these defects is not a location that one would normally examine, since the availability of the location disappears due to the lithography process steps that are applied subsequent to the “intermediate layer.” In other words, the damaged underlying material (e.g., silicon substrate) is overlaid with another layer that obscures an examination of the damaged area. More specifically, the damaged area typically results from a focused discharge point where the discharge current passes through the substrate and causes crystalline damage, i.e., atomic scale disruption. In a worst case, it can melt the local area of the substrate. However, the resulting damage is overlaid by another layer (e.g., an oxide layer), leaving underneath an irreparable weak spot. This weak spot represents a breakdown opportunity, and compromises the subsequent oxide formation. For example, in the formation of a capacitor, the charge-related damages would form in the bottom plate of the capacitor, with such damages obscured by the formation of the actual dielectric layer and top plate of the capacitor. Since the charge-related damages are irreparable, the resulting capacitor would exhibit unacceptable breakdown performance characteristics.

To further highlight the unexpected nature of the “intermediate layer” yield loss mechanism is the lack of readily available options by lithography track vendors to support the desired change in process. Track vendors provide insight into the conventional thinking as to the types of process stations that are required to support their lithography client base. The requested insertion of a weak acidic rinse step in the lithography track process offering was met by a complete absence of any such capability. In fact, the cost suggested by track vendors to provide such an acidic rinse step confirmed that such a step represented a complete departure from the conventional thinking in the lithography industry. Even the choice of an acidic rinse in a lithographic track ran counter to the prevailing wisdom since lithographic developer is a base solution (pH greater than 7) and thus acidic solutions are considered to be antithetical to the range of chemicals normally used in a lithography process.

Further evidence of the unexpected nature of the “intermediate layer” yield loss mechanism is the relative comfort that charging phenomena are intentionally used in semiconductor lithography processing. For example, reactive ion etching is a deliberate attempt to charge the wafer surface using very high amounts of charge. Thus, charging is not the mechanism that would be expected to be responsible for the “intermediate layer” yield loss.

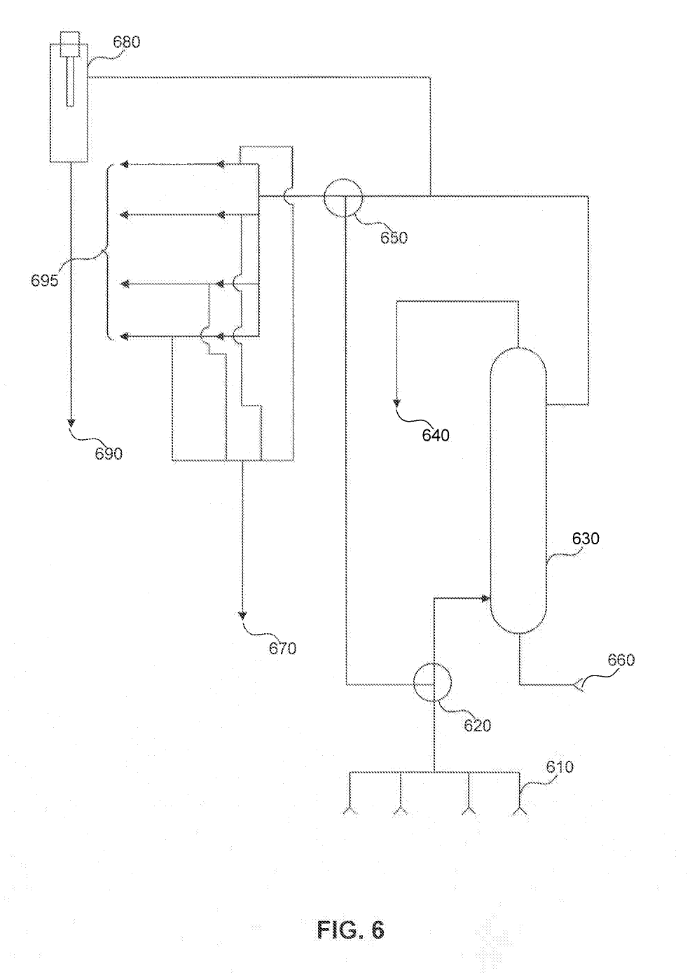

In an exemplary embodiment of the present invention, an acidic rinse can be introduced into the lithography process, as illustrated in FIG. 6. Deionized (DI) water is introduced via the one or more inputs 610 and enters valve 620. The DI water can be generated using municipal water, reclaimed water or the like as the starting point for the deionization process. Valve 620 can direct the DI water to either valve 650 or sparge 630. Sparge 630 also receives carbon diode via input 660 and outputs the result of bubbling carbon dioxide through the DI water to valve 650. The bubbling carbon dioxide results in the formation of carbonic acid. A sample of the output is also directed to a resistivity sensor 680, with the sample exiting at a drain 690 that is connected to resistivity sensor 680. Excess carbon dioxide that does not dissolve in the DI water exits from sparge 630 via exhaust 640. Valve 650 directs either DI water or DI water that includes dissolved carbon dioxide to a variety of outputs 695 for use in the lithography system. Excess of the directed DI Water or DI water that includes dissolved carbon dioxide exits at drain 670. Using this embodiment, either DI water or DI water with dissolved carbon dioxide can be directed, as required, to the relevant stations in the lithographic process line.

The use of dissolved carbon dioxide in water (resulting in carbonic acid) is intended to be exemplary and not limiting. The scope of the present invention include the use of any weak acidic rinse that is compatible with the lithographic process to which it will be used. For example, the scope of the present invention also includes the use of formic acid, acetic acid or other weak organic acid. In any of these forms, the weak acid will neutralize or consume the free hydroxyl ions before the DI water is introduced to the wafer surface, thus reducing the charging mechanism of the DI rinse.

Following the application of a weak acidic rinse, additional lithographic processing steps may be performed, with the knowledge that the in-process semiconductor structure is free from charge-induced damage. For example, a further layer can be overlaid in a region previously occupied by the removed intermediate layer (e.g., dielectric layer). For example, the further layer can include an oxide layer. Following the provision of the further layer, a conductive layer can be formed over the further layer to form a dielectric capacitor. These scenarios are merely exemplary of successive lithographic process steps, and not limiting. One of ordinary skill in the art would recognize the applicability of embodiments of the present invention to other scenarios whereby semiconductor structures are fabricated following the removal of an intermediate layer. Such semiconductor structures would rely on the benefit that the in-process semiconductor structure is free from charge-induced damage.

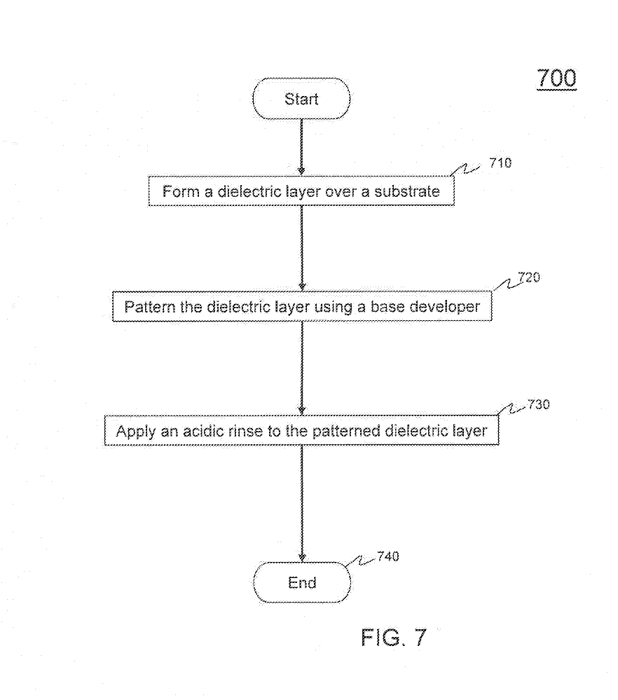

FIG. 7 provides a flowchart of a method that fabricates a damage-free dielectric layer, according to an embodiment of the current invention.

The process begins at step 710. In step 710, a dielectric layer is formed over a substrate. In an embodiment, dielectric layer 520 is formed over substrate 510. As discussed above, substrate 510 can include bulk semiconductor substrates such as silicon, bulk semiconductor substrates together with added layers such epitaxial layers or disposed layers of other materials.

In step 720, the dielectric layer is patterned using a developer with a pH greater than 7. In an embodiment, dielectric layer 520 is patterned with a base developer.

In step 730, an acidic rinse is applied to the patterned dielectric layer. In an embodiment, the application of the acidic rinse involves the addition of an acidic component to a post-develop de-ionized (DI) water rinse. In another embodiment, the application of the acidic rinse is performed prior to a dry processing step. In yet another embodiment, the acidic rinse is a weak acidic rinse. In a further embodiment carbon dioxide dissolved in water (carbonic acid) is applied to the patterned dielectric layer. In a still further embodiment, carbonic acid having a resistivity of 30 to 150 K-ohm-cm is applied for sufficient time to adequately rinse the wafer. In a further embodiment, a weak acidic rinse is applied that includes at least one of carbonic acid or carboxylic acid. Various embodiments remove all restriction on rinsing rime and its causal connection to charging-induced damage. In other embodiments, different acidic rinses with different concentrations can be used for different periods of time.

At step 740, method 700 ends.

As an additional benefit of the above embodiment, the elimination of surface charge on the wafers after lithographic process substantially reduces sticking power of particles on the wafer surface which are typically held by static electrical attraction. This reduction of surface particular can result in further increase of semiconductor yields.

It is to be appreciated that the Detailed Description section, and not the Summary and Abstract sections, is intended to be used to interpret the claims. The Summary and Abstract sections may set forth one or more but not all exemplary embodiments of the current invention as contemplated by the inventor(s), and thus, are not intended to limit the current invention and the appended claims any way.

The current invention has been described above with the aid of functional building blocks illustrating the implementation of specified functions and relationships thereof. The boundaries of these functional building blocks have been arbitrarily defined herein for the convenience of the description. Alternate boundaries can be defined so long as the specified functions and relationships thereof are appropriately performed.

The foregoing description of the specific embodiments will so fully reveal the general nature of the invention that others can, by applying knowledge within the skill of the art, readily modify and/or adapt for various applications such specific embodiments, without undue experimentation, without departing from the general concept of the current invention. Therefore, such adaptations and modifications are intended to be within the meaning and range of equivalents of the disclosed embodiments, based on the teaching and guidance presented herein. It is to be understood that the phraseology or terminology herein is for the purpose of description and not of limitation, such that the terminology or phraseology of the present specification is to be interpreted by the skilled artisan in light of the teachings and guidance.

The breadth and scope of the current invention should not be limited by any of the above-described exemplary embodiments, but should be defined only in accordance with the following claims and their equivalents.

The claims in the instant application are different than those of the parent application or other related applications. The Applicant therefore rescinds any disclaimer of claim scope made in the parent application or any predecessor application in relation to the instant application. The Examiner is therefore advised that any such previous disclaimer and the cited references that it was made to avoid, may need to be revisited. Further, the Examiner is also reminded that any disclaimer made in the instant application should not be read into or against the parent application.

What is claimed is:

1. A method comprising:
forming a dielectric layer over a substrate, the dielectric layer having a thickness;
patterning the dielectric layer, the patterning including using a developer having a pH greater than 7; and
applying a weak acidic rinse to the patterned dielectric layer.

2. The method of claim 1, wherein the dielectric layer comprises silicon dioxide.

3. The method of claim 2, further comprising:
removing the dielectric layer, wherein the dielectric layer is a sacrificial layer.

4. The method of claim 1, wherein the applying a weak acidic rinse includes adding an acidic component to a post develop de-ionized(DI) water rinse.

5. The method of claim 1, further comprising:
forming the weak acidic rinse by using a sparge to mix carbon dioxide with de-ionized. (DI) water.

6. The method of claim 5, wherein the water comprises incoming reclaimed water.

7. The method of claim 5, wherein the water comprises incoming municipal water.

8. The method of claim 5, wherein the water comprises incoming de-ionized (DI) water having small concentrations of non-volatile organic impurities.

9. The method of claim 8, wherein the non-volatile organic contaminant includes at least one organic compound, the at least one organic compound including carbamide, ethanol, propanal or isopropyl alcohol.

10. The method of claim 1, wherein the applying a weak acidic rinse comprises applying at least one of carbonic acid or carboxylic acid.

11. The method of claim 1, wherein the thickness lies within the range of 70 to 120 Angstroms.

12. The method of claim 1, further comprising:
overlaying a further layer in a region previously occupied by the removed dielectric layer.

13. The method of claim 1, further comprising:
overlaying a further layer in a region previously occupied by the removed dielectric layer; and
forming a pad over the further layer to thereby form a dielectric capacitor.

14. The method of claim 13, wherein the further layer comprises an oxide.

15. The method of claim 1, wherein the applying a weak acidic rinse is performed prior to applying a dry processing step.

16. A lithographic structure, comprising:
a substrate;
a patterned dielectric layer formed on the substrate using a base developer solution, wherein a thickness of the patterned dielectric layer lies within a range of vulnerability to charge-induced damage, and wherein an interface between the substrate and the patterned dielectric layer is tree from the charge-induced damage.

17. The lithographic structure of claim 16, wherein the dielectric layer comprises silicon dioxide.

18. The lithographic structure of claim 16, wherein the dielectric layer comprises a sacrificial layer.

19. The lithographic structure of claim 16, wherein the substrate is a silicon wafer.

20. The lithographic structure of claim 16, wherein the range of vulnerability to charge-induced damage is 70 to 120 Angstroms.
